(19) United States
(12) Patent Application Publication
(10) Pub. No.: US 2012/0018755 A1
(43) Pub. Date: Jan. 26, 2012

(54) LIGHT EMITTING DEVICES WITH EMBEDDED VOID-GAP STRUCTURES THROUGH BONDING OF STRUCTURED MATERIALS ON ACTIVE DEVICES

(75) Inventors: James S. Speck, Goleta, CA (US); Claude C. A. Weisbuch, Paris (FR); Elison de Nazareth Matioli, Goleta, CA (US)

(73) Assignee: THE REGENTS OF THE UNIVERSITY OF CALIFORNIA, Oakland, CA (US)

(21) Appl. No.: 12/871,644

(22) Filed: Aug. 30, 2010

Related U.S. Application Data
(60) Provisional application No. 61/367,239, filed on Jul. 23, 2010.

(51) Int. Cl. H01L 33/60; H01L 33/00

(52) U.S. Cl. 257/98; 438/29; 257/E33.072; 257/E33.001

(57) ABSTRACT

A method of fabricating optoelectronic devices with embedded void-gap structures on semiconductor layers through bonding is provided. The embedded void-gaps are fabricated on a semiconductor structure by bonding a patterned layer or slab onto a flat surface, or by bonding a flat layer or slab onto a patterned surface. The void-gaps can be filled with air, gases, conductive or dielectric materials, or other substances, in order to provide better isolation of optical modes from dissipative regions, or better light extraction properties.

### CROSS-REFERENCE TO RELATED APPLICATIONS

This application claims the benefit under 35 U.S.C. Section 119(e) of co-pending and commonly assigned U.S. Provisional Application Ser. No. 61/238,003, filed on Aug. 28, 2009, by James S. Speck, Claude C. A. Weisbuch, and Elison de Nazareth Matioli, entitled “LIGHT EMITTING DEVICES WITH EMBEDDED AIR GAP STRUCTURES THROUGH BINDING OF STRUCTURED MATERIALS ON ACTIVE DEVICES,” attorney's docket number 30794.310-US-P1 (2009-494-1), which application is incorporated by reference herein.

This application is related to the following patents, publications and applications:

U.S. Pat. No. 7,723,745, issued May 25, 2010, published Jun. 5, 2008, as U.S. Patent Publication 2008/0128737, filed Feb. 13, 2008, as U.S. Utility application Ser. No. 12/030,697, by Claude C. A. Weisbuch, Aurelien J. F. David, James S. Speck, and Steven P. DenBaars, entitled “HORIZONTAL EMITTING, VERTICLE EMITTING, BEAM SHAPED, DISTRIBUTED FEEDBACK (DFB) LASERS BY GROWTH OVER A PATTERNED SUBSTRATE,” attorneys' docket number 30794.121-US-C1 (2005-144-2), which is a continuation of U.S. Pat. No. 7,345,298, issued Mar. 18, 2008, published Aug. 31, 2006, as U.S. Patent Publication 2006/0194359, filed Feb. 28, 2005, as U.S. Utility application Ser. No. 11/067,957, by Claude C. A. Weisbuch, Aurelien J. F. David, James S. Speck and Steven P. DenBaars, entitled “HORIZONTAL EMITTING, VERTICAL EMITTING, BEAM SHAPED, DISTRIBUTED FEEDBACK (DFB) LASERS BY GROWTH OVER A PATTERNED SUBSTRATE,” attorneys docket number 2005-144-1 (30794.121-US-01);

U.S. Utility application Ser. No. 12/822,888, filed on Jun. 24, 2010, by Claude C. A. Weisbuch and Shuji Nakamura, entitled “HORIZONTAL EMITTING, VERTICAL EMITTING, BEAM SHAPED, DISTRIBUTED FEEDBACK (DFB) LASERS FABRICATED BY GROWTH OVER PATTERNED SUBSTRATE WITH MULTIPLE OVERGROWTH,” attorneys docket number 2005-721-3 (30794.143-US-C1), which is a continuation of U.S. Pat. No. 7,768,024, issued Aug. 3, 2010, published Jun. 7, 2007, as U.S. Patent Publication No. 2007/0125995, filed Dec. 4, 2006, as U.S. Utility application Ser. No. 11/633,148, by Claude C. A. Weisbuch and Shuji Nakamura, entitled “IMPROVED HORIZONTAL EMITTING, VERTICAL EMITTING, BEAM SHAPED, DISTRIBUTED FEEDBACK (DFB) LASERS FABRICATED BY GROWTH OVER A PATTERNED SUBSTRATE WITH MULTIPLE OVERGROWTH,” attorneys docket number 2005-721-2 (30794.143-US-U1), which claims the benefit under 35 U.S.C Section 119(e) of U.S. Provisional Application Ser. No. 60/741,935, filed on Dec. 2, 2005, by Claude C. A. Weisbuch and Shuji Nakamura, entitled “IMPROVED HORIZONTAL EMITTING, VERTICAL EMITTING, BEAM SHAPED, DISTRIBUTED FEEDBACK (DFB) LASERS FABRICATED BY GROWTH OVER A PATTERNED SUBSTRATE WITH MULTIPLE OVERGROWTH,” attorneys' docket number 30794.143-US-P1 (2005-721);

U.S. Utility application Ser. No. 12/834,453, filed on Jul. 12, 2010, by Aurelien J. F. David, Claude C. A. Weisbuch and Steven P. DenBaars, entitled “HIGH EFFICIENCY LIGHT EMITTING DIODE (LED) WITH OPTIMIZED PHOTONIC CRYSTAL EXTRACTOR,” attorneys docket number 2005-198-3 (30794.126-US-C1), which is a continuation of U.S. Patent Publication No. 2009/0305446, published on Dec. 10, 2009, filed on Aug. 13, 2009, as U.S. Utility application Ser. No. 12/541,061, by Aurelien J. F. David, Claude C. A. Weisbuch and Steven P. DenBaars, entitled “HIGH EFFICIENCY LIGHT EMITTING DIODE (LED) WITH OPTIMIZED PHOTONIC CRYSTAL EXTRACTOR,” attorneys docket number 2005-198-2 (30794.126-US-D1), which is a divisional of U.S. Pat. No. 7,582,910, issued Sep. 1, 2009, published Aug. 31, 2006, as U.S. Patent Publication No. 2006/0192217, filed Feb. 28, 2005, as U.S. Utility application Ser. No. 11/067,956, by Aurelien J. F. David, Claude C. A. Weisbuch and Steven P. DenBaars, entitled “HIGH EFFICIENCY LIGHT EMITTING DIODE (LED) WITH OPTIMIZED PHOTONIC CRYSTAL EXTRACTOR,” attorneys docket number 2005-198-1 (30794.126-US-01);

U.S. Utility application Ser. No. 12/793,862, filed on Jun. 4, 2010, by Claude C. A. Weisbuch, Aurelien J. F. David, James S. Speck and Steven P. DenBaars, entitled “SINGLE OR MULTI-COLOR HIGH EFFICIENCY LIGHT EMITTING DIODE (LED) BY GROWTH OVER A PATTERNED SUBSTRATE,” attorneys docket number 2005-145-3 (30794.122-US-C2), which is a continuation of U.S. Pat. No. 7,755,096, issued Jul. 13, 2010, published Apr. 17, 2008, as U.S. Patent Publication No. 2008/0087909, filed Oct. 24, 2007, as U.S. Utility application Ser. No. 11/923,414, by Claude C. A. Weisbuch, Aurelien J. F. David, James S. Speck and Steven P. DenBaars, entitled “SINGLE OR MULTI-COLOR HIGH EFFICIENCY LIGHT EMITTING DIODE (LED) BY GROWTH OVER A PATTERNED SUBSTRATE,” attorneys docket number 2005-145-2 (30794.122-US-C1), which is a continuation of U.S. Pat. No. 7,291,864, issued Nov. 6, 2007, published Sep. 14, 2006, as U.S. Patent Publication 2006/0202226, filed Feb. 28, 2005, as U.S. Utility application Ser. No. 11/067,910, by Claude C. A. Weisbuch, Aurelien J. F. David, James S. Speck and Steven P. DenBaars, entitled “SINGLE OR MULTI-COLOR HIGH EFFICIENCY LIGHT EMITTING DIODE (LED) BY GROWTH OVER A PATTERNED SUBSTRATE,” attorneys docket number 2005-145-1 (30794.122-US-01); and

U.S. Provisional Application Ser. No. 61/367,239, filed on Jul. 23, 2010, by Elison de Nazareth Matioli, Claude C. A. Weisbuch, James S. Speck and Evelyn L. Hu, entitled “OPTOELECTRONIC DEVICES WITH EMBEDDED VOID STRUTURES,” attorneys docket number 2009-493-1 (30794.385-US-P1);

all of which are incorporated by reference herein.

### BACKGROUND OF THE INVENTION

1. Field of the Invention

The invention relates to structuring materials to obtain better light emitting diodes and lasers through high extraction efficiency or better isolation of active layers from metal electrodes, and specifically, to light emitting devices with embedded void-gap structures through bonding of structured materials on active devices.

2. Description of the Related Art

This invention relates to improving and fabricating semiconductor light emitting diodes (LEDs) and lasers relying on buried grating mirrors and photonic crystals (PhCs), and more particularly, to new structures beyond those obtained by growth on substrates patterned by these gratings and photonic crystals, as described in the cross-referenced patents, publications and applications set forth above. These cross-referenced patents, publications and applications describe ways to incorporate a low index layer in the grown structures, wherein the low index layer helps confine light in the vertical direction.

For PhC LEDs, as described in U.S. Patent Publication No. 2006/0192217, which is incorporated by reference herein, the purpose of that layer is to diminish or forbid optical modes that are not efficiently extracted by a surface PhC.

In typical PhC LEDs, buffer and active layers are typically made in GaN, the low index confining layer in AlGaN, and the quantum wells (QWs) in GaInN, as described in U.S. Patent Publication No. 2006/0192217, which is incorporated by reference herein. This structure differs from typical double heterostructure LEDs where two low index layers are used on both sides of the active region to confine carriers in the active layers. In U.S. Patent Publication No. 2006/0192217, which is incorporated by reference herein, only one low index layer is used on the side of the active layer opposite to the PhC, which will favor emission into guided optical modes which interact strongly with the PhC. Putting another low index layer, as used in double heterostructure LEDs, between the active layer and PhC would confine the modes around the active layer and prevent them from overlapping with the PhC, and therefore preventing the PhC from efficiently diffracting guided modes into air.

The confining layer can also be obtained through a lateral epitaxial overgrowth (LEO) of nitride-based material over a patterned growth masking layer, as described in U.S. Patent Publication No. 2008/0087909, which is incorporated by reference herein. In that case, the composite layer comprising the mask material and the overgrown material constitutes the low index confining layer and it can also act as the light extracting PhC by proper design.

In in-plane emitting lasers, the laser mode usually interacts quite strongly with the metal top electrode, leading to propagation losses which increase threshold current and diminish power efficiency. The doped semiconductor contact layers can also induce propagation losses, in particular, the p-type doped contact layer (see e.g. S. Uchida et al., IEEE Journal Of Selected Topics In Quantum Electronics, Vol. 9, No. 5, September/October 2003, p. 1252, which is incorporated by reference herein).

Usually, optical confining layers are used to confine the laser mode away from the metal top electrode and the contact layers. Such confining layers have an index of refraction lower than that of the active layer, and therefore somewhat confine the optical wave into the active region, thus leading to a stronger interaction of the laser mode with the active material, for instance decreasing the lasing threshold current, and to a weaker interaction between that mode and the contact layers and electrode.

However, there are compromises. Thick, high index (meaning high bandgap) confining layers (made of AlGaN material, for example), which would have good confinement properties, also have poor current conduction properties, leading to increased device resistance and operating voltage. Moreover, the growth of high Al content materials is also hard to achieve without introducing large dislocation densities or even cracks due to the lattice mismatch between AlGaN and the other materials of the structure. Due to these limitations, currently available indices and thicknesses of the confining layers in lasers have insufficient confinement properties and they lead to an overflow of the laser mode and its interaction with the metal electrode.

Better confining layers for lasers can be obtained through the LEO of nitride-based material over a patterned growth masking layer, as described in U.S. Patent Publication Nos. 2006/0194359 and 2007/0125995, which are incorporated by reference herein. Very good confinement properties can be obtained due to the high index difference between the mask material (it can even be air), while conserving good electrical conduction properties due to the perforations of the mask material containing good conductive semiconductor material.

While embedded dielectric structures can be obtained by various growth techniques such as LEO (see, e.g., U.S. Patent Publication Nos. 2006/0194359, 2007/0125995, 2006/0192217, and 2008/0087909, which are incorporated by reference herein), various structures of interest can be obtained by direct bonding of a passive structured material on the active LED structure, as described in more detail in this application.

### SUMMARY OF THE INVENTION

To overcome the limitations in the prior art described above, and to overcome other limitations that will become apparent upon reading and understanding the present specification, the present invention discloses various bonding techniques and structures to obtain structured layers within semiconductors devices. The patterns of the structured layers can be random or periodic and arranged in one, two or three dimensions.

A simple method of fabricating optoelectronic devices with embedded void-gap structures through bonding on structured semiconductor materials is provided. Specifically, embedded void-gaps are fabricated on a semiconductor structure by bonding of a patterned material slab on a flat semiconductor surface or by bonding of a flat slab over a patterned structure. The void-gaps can be filled with air, conductive or dielectric materials and can be advantageous for optoelectronic device applications for several reasons such as better isolation of optical modes from dissipative regions in lasers or light extraction properties for LEDs.

This is an easy fabrication method, because it involves just materials bonding. This is a planar and manufacturable method for embedded void-gaps structures. The void-gaps can be filled with air or other materials. Multiple bondings can prove useful for given applications or implementations.

### BRIEF DESCRIPTION OF THE DRAWINGS

Referring now to the drawings in which like reference numbers represent corresponding parts throughout:

FIG. 1 is a schematic diagram of emitted modes in a thick active layer PhC LED structure.

FIG. 2 is a schematic diagram of emitted modes in an active layer PhC LED structure possessing an AlGaN optical confining layer.

FIG. 3 is a schematic diagram of a laser structure with size values for the active layer and AlGaN optical confining layers.

FIG. 4 is a schematic diagram of a laser structure incorporating an embedded dielectric patterned layer acting as top confining layer and also eventually possessing PhC properties.

FIG. 5 is a schematic diagram of a laser structure incorporating embedded void-gaps features, wherein the patterned features are produced in a portion of the material before bonding the material to the active semiconductor structure.

FIG. 6 is a schematic diagram of a laser or LED structure incorporating embedded void-gaps features, wherein the void pattern is in the submicron size range so as to extract light through diffraction effects.

FIG. 7 is a schematic diagram of an LED structure incorporating embedded void-gap structures, wherein the void features are micron sized or larger so as to extract light through geometrical optics effects.

FIG. 8 is a schematic diagram of an LED structure incorporating embedded void-gap structures, wherein light is extracted through geometrical optics effects and the substrate has been removed.

FIG. 9 is a schematic diagram of an LED structure incorporating embedded void-gap structures, wherein light is extracted through geometrical optics effects, the substrate has been removed, and the void-gaps are obtained in two steps, by a double deposition or bonding of materials, the first one being deposited or bonded having patterned air holes.

FIG. 10 is a schematic diagram of an LED structure incorporating embedded void-gap structures, wherein the substrate has been removed and subsequently the semiconductor was thinned to a sub-micron thickness followed by a bonding of a patterned material on the bottom surface.

FIG. 11 is a schematic diagram of an LED structure incorporating embedded void-gap structures, wherein two or more patterned layers were piled up through bonding and precisely shifted to form a three-dimensional (3D) periodic structure.

FIG. 12 is a schematic diagram of an LED structure incorporating embedded void-gap structures, wherein the bonded patterned layer contains frequency converter materials.

FIG. 13 is a schematic diagram of an LED structure incorporating concepts from FIGS. 11 and 12.

FIG. 14 is a schematic diagram of an LED structure, wherein the active device was patterned to create a PhC and a flat layer was bonded over the PhC.

FIG. 15 is a flowchart that illustrates the process steps performed according to the preferred embodiment of the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The present invention describes a method for creating embedded void-gap structures, such as void-gap PhCs, for optoelectronic devices, wherein the void-gap structures are embedded in one or more layers that are then bonded to a top or bottom surface of the active device structure. “Void-gap” as used herein is intended to mean voids, gaps, holes, perforations, etc., created in one or more of layers of the structure.

The void-gaps may be filled with air, gas, conductive material, dielectric material, or other substances. Moreover, the void-gaps may comprise polygonal, cylindrical or spherical shaped features, randomly shaped features, randomly distributed features, periodically or quasi-periodically distributed shaped features. In addition, the void-gaps may be arranged in one-dimensional (1D), two-dimensional (2D) or three-dimensional (3D) patterns. The void-gaps also may be contiguously connected, formed of connecting holes, formed of connecting pillars, or formed of both connecting holes and connecting pillars. These and further aspects of the present invention are described in more detail below.

The operation of the concept developed in this invention relies on refractive index differences. Creating patterns of void-gaps in the material layers to be bonded and leaving the resulting void-gaps empty or filling them with a substance having a refractive index different from the material layers or the active device structure achieves this property.

The method disclosed by the present invention does not make use of the growth of embedded material on some specific regions, such as dielectrics, to form the void-gaps. Instead, in the present invention, the void-gaps are naturally formed during bonding, either because the bonded layers have been patterned before being bonded to the active device structure, or because bonding is done over a patterned surface of the active device structure.

While the present invention discloses a simple method, the structure growth resulting therefrom retains a planar aspect that makes it manufacturable at low cost.

Technical Description

Void-gaps, which typically have a lower index of refraction as compared to surrounding material, are a desired feature in devices such as LEDs or lasers. They mainly serve two purposes. The first purpose is to provide optical confinement due to the lower average index of refraction of the layer that contains the void-gaps.

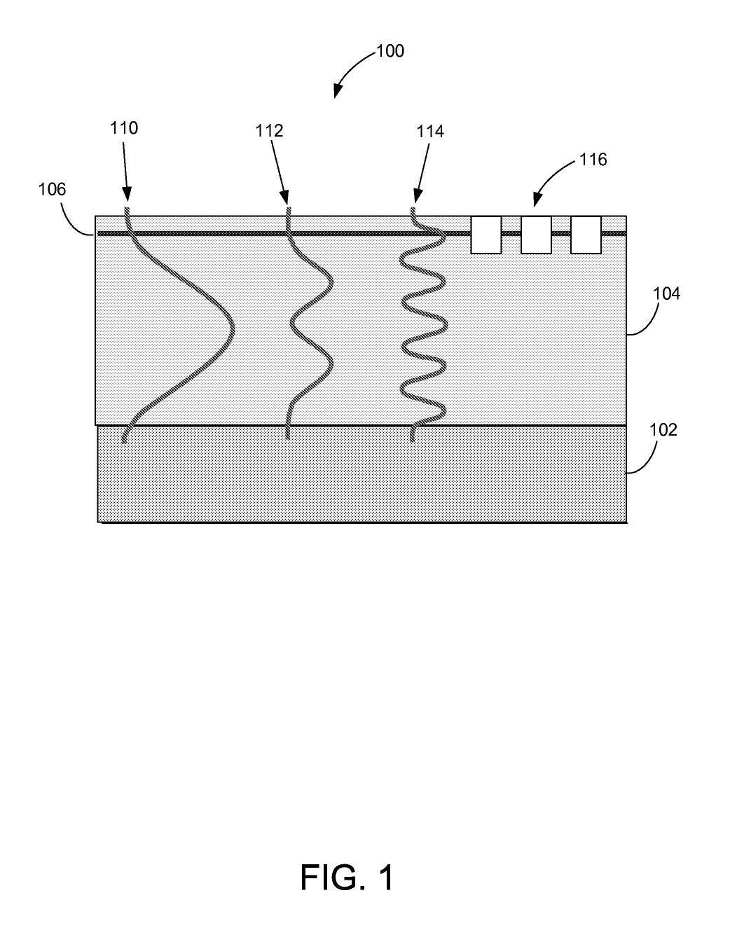

FIG. 1 is a schematic diagram of emitted modes in a thick active layer PhC LED structure. The LED structure 100 includes a sapphire substrate 102, GaN layer 104, quantum well layer 106, and PhC 108. Also shown are the guided modes of the emitted light, including two low order modes 110, 112 and one high order mode 114. Because the LED 100 does not have void-gap layers, the optical modes 110, 112, 114 are widely delocalized over the structure 100 and the low-order guided modes 110, 112 interact weakly with light extracting structures such as PhCs 108. Specifically, the low order guided modes 110, 112 have a small overlap with the PhC 108, which is then rather inefficient to extract such guided modes 110, 112.

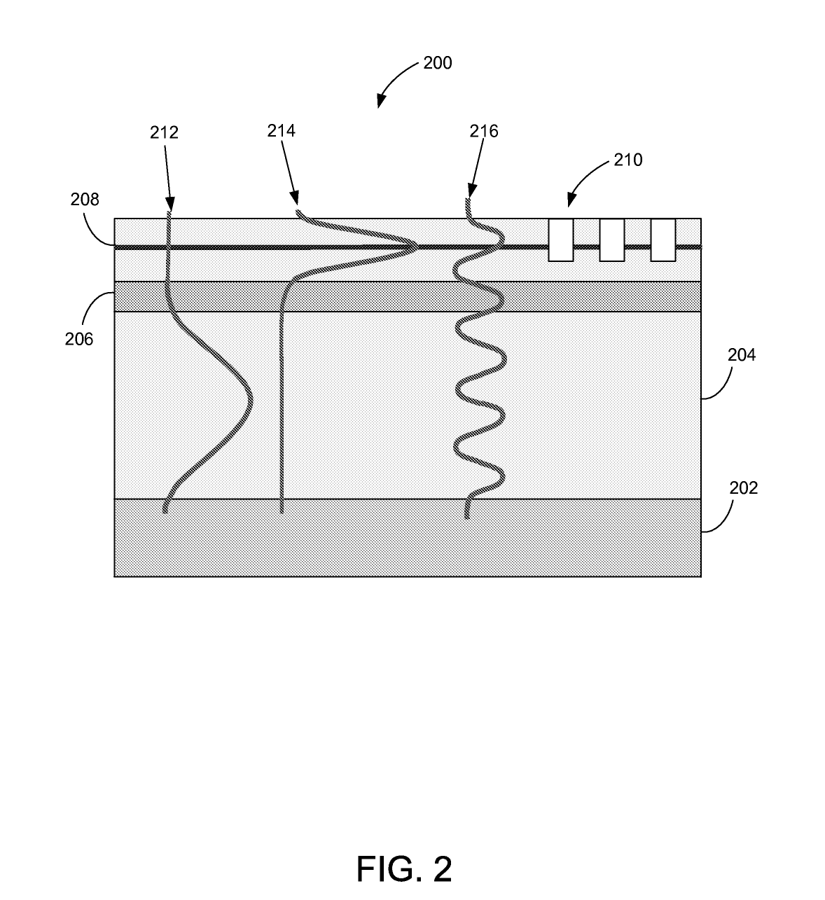

FIG. 2 is a schematic diagram of emitted modes in an active layer PhC LED structure possessing an AlGaN optical confining layer. The LED structure 200 includes a sapphire substrate 202, GaN layer 204, AlGaN optical confining layer 206, quantum well layer 208, and PhC 210. Also shown are the guided modes of the emitted light, including two low order modes 212, 214 and one high order mode 216. Modes which are excited by the spontaneous emission from the quantum wells 208 are of three types: low order guided modes 212 located below the AlGaN optical confining layer 206, which have a small overlap with the PhC 210 and are then rather poorly extracted, but, at the same time, they are only weakly excited by the quantum wells 208 with which they have a poor overlap; low order modes 214 located above the AlGaN optical confining layer 206 which will interact strongly with the PhC 210 and will therefore be efficiently extracted; high order modes 216 unconfined by the AlGaN optical confining layer 206 and which are well extracted as they overlap well with the PhC 210. Specifically, the inclusion of the AlGaN optical confining layer 206 selects emissions 214 from quantum wells, which are well extracted by surface PhCs 210.

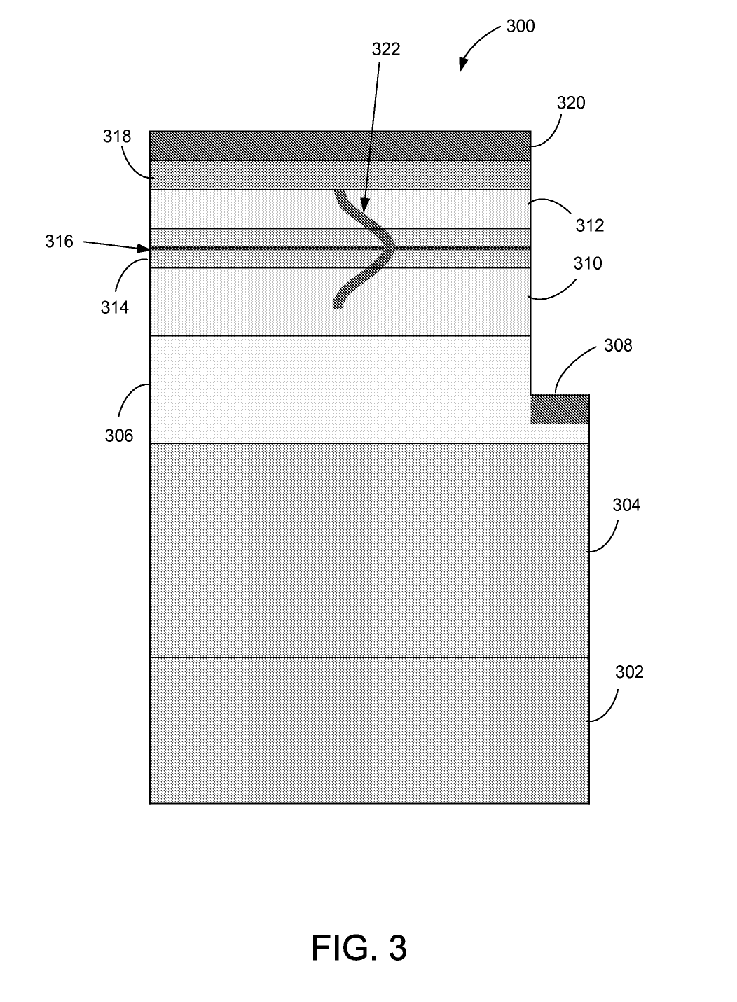

FIG. 3 is a schematic diagram of a laser structure with size values for the active layer and AlGaN optical confining layers. The laser structure 300 includes a substrate 302, buffer layer 304, GaN n-type contact layer 306, bottom metal electrode 308, AlGaN optical confining layers 310, 312, GaN layer 314, quantum well layer 316, GaN p-type contact layer 318, and top metal electrode 320. Also shown is the optical laser wave 322.

The AlGaN optical confining layers 310, 312 are low index layers that are in high demand for lasers for optical confinement purposes. Specifically, for an in-plane laser, such as shown in FIG. 3, the AlGaN optical confining layers 310, 312 help confine light around the light emitting quantum wells 316 with two purposes: the interaction is increased between the lasing mode and the quantum wells, leading to a larger modal gain and, hence, diminishing threshold current. The mode is confined away from the doped contact layers and the electrodes, diminishing modal propagation losses.

The available materials to achieve such low index set limits to the reachable optical confinement properties. In a GaN-based system, the incorporation of Al is severely limited by metallurgical constraints (strain induces dislocation or crack formation at high Al fractions or large thicknesses), thus leading to small index contrast and insufficient optical confinement. Therefore, the high index contrast brought by void-gaps is most welcome.

The second purpose of low index layers relies on their capability, when they are patterned, to extract light efficiently in LEDs, either through diffraction effects (PhC extraction) or through ray randomization by multiple reflections in geometrical optics conditions. In lasers, such patterns can be used for making cavity mirrors, wavelength selection, such as by distributed feedback (DFB) lasers, or vertical emission, such as surface emitting in-plane lasers with second-order distributed Bragg reflector (DBR) mirrors.

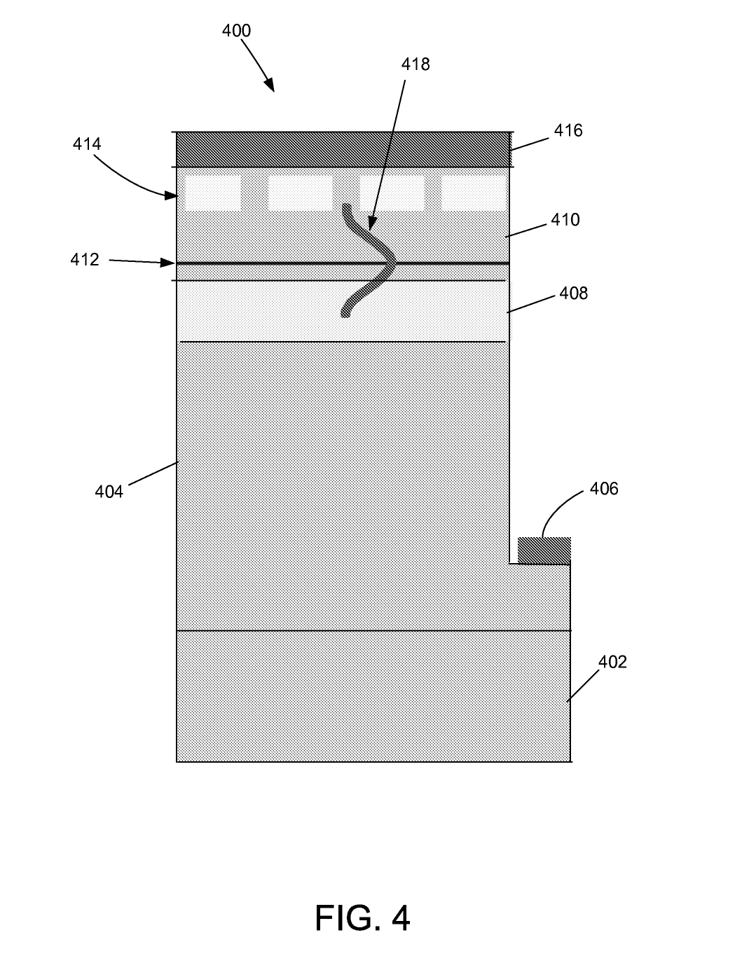

FIG. 4 is a schematic diagram of a laser structure incorporating an embedded dielectric patterned layer acting as top confining layer and also eventually possessing PhC properties. The laser structure 400 includes a substrate 402, buffer layer 404, bottom metal electrode 406, AlGaN optical confining layer 408, GaN layer 410, quantum well layer 412, dielectric pattern mask 414, and top metal electrode 416. Also shown is the optical laser wave 418. The patterned layer 414 is a low index layer made of a dielectric material. The patterned layer 414 can be as thick as desired to guarantee good optical confinement since there are no metallurgical constraints.

Methods to obtain optoelectronic devices with embedded air or dielectric voids are described in the cross-referenced patents, publications and application set forth above, namely, U.S. Patent Publication Nos. 2006/0194359, 2007/0125995, and 2006/0192217, which are incorporated by reference herein. However, these methods rely on the semiconductor epitaxial overgrowth over a patterned layer (made of dielectric or semiconductor); hence, the fabrication of such devices is a more complex process, including an initial growth step followed by a fabrication step where the pattern is made and, subsequently, another growth step.

The present invention proposes an improved method of fabrication of embedded patterned structures by bonding a patterned material to an active device. The method according to the present invention decouples the device from the patterned layer fabrications, which allows a much more flexible design of the patterned structure, in terms of the materials filling the pattern holes, the period, shape, size and depth of the pattern holes. Additionally, separating (and possibly parallelizing) the process steps for the active device and the patterned material makes the overall process more robust and less sensitive to problems in separate steps.

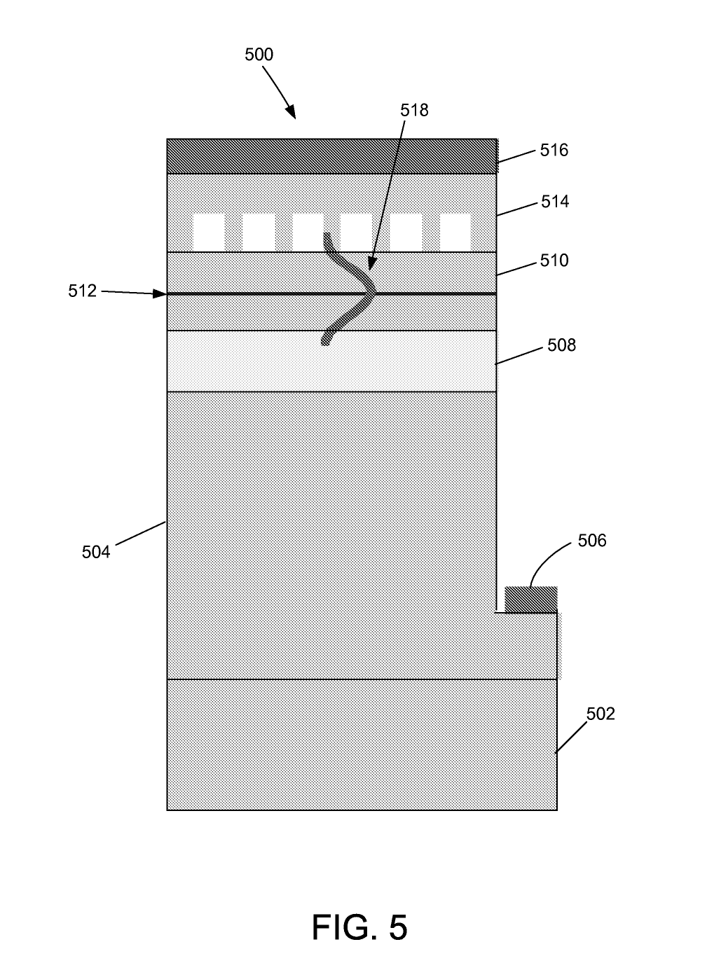

FIG. 5 is a schematic diagram of a laser structure incorporating embedded void-gaps features according to the present invention, wherein the patterned features are produced in a portion of the material before bonding the material to the active semiconductor structure. The laser structure 500 includes a substrate 502, buffer layer 504, bottom metal electrode 506, AlGaN optical confining layer 508, GaN layer 510, quantum well layer 512, bonded patterned material layer 514, and top metal electrode 516, wherein the GaN layer 510 may comprise multiple doped or undoped layers positioned above and below quantum well layer 512 and the quantum well layer 512 itself may comprise a stack of layers (and this also holds for the devices described below). Also shown is the optical laser wave 518. The bonded patterned material layer 514 may be bonded to either the top or bottom surface of a semiconductor structure containing an active layer 512, and can also incorporate a metallic layer 516 serving as an electrode.

Several configurations can be considered for the patterned layer bonded to the active device structure. The pattern of the bonded layer can be periodic, quasi-periodic or random. A periodic lattice would form an embedded photonic crystal structure, which could be useful due to its photonic band gap properties, as well its diffraction properties. Quasi-periodic patterns, such as Penrose lattices, could potentially increase the directions in which diffraction occurs, which would make light emission of the optoelectronic device more omnidirectional.

A completely random lattice could also be created. In this case, the light scattering due to the embedded pattern randomizes the guided light, thereby increasing the light extraction efficiency of the optoelectronic device.

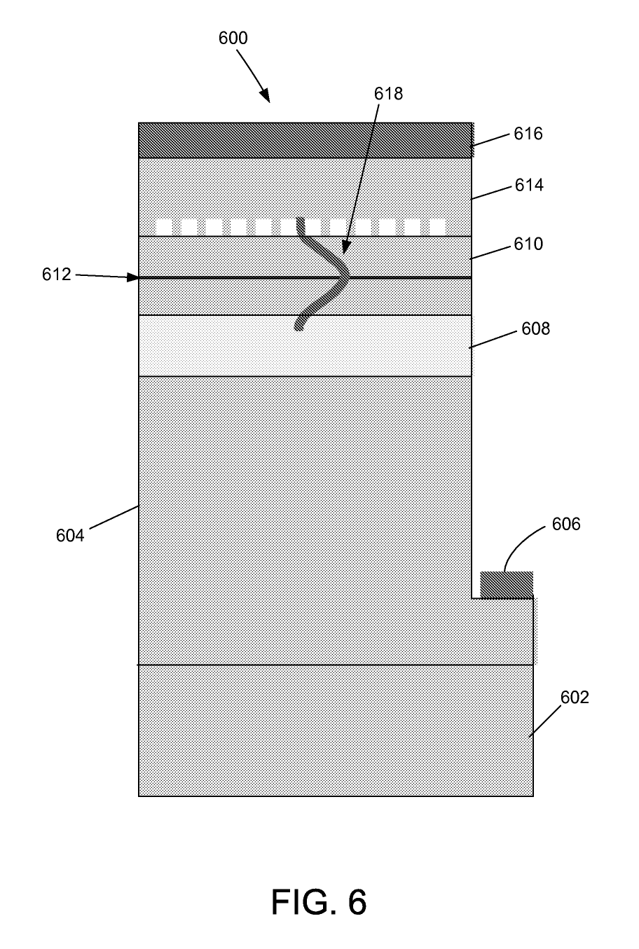

FIG. 6 is a schematic diagram of a laser or LED structure incorporating embedded void-gaps features according to the present invention, wherein the void pattern is in the submicron size range so as to extract light through diffraction effects. The laser structure 600 includes a substrate 602, buffer layer 604, bottom metal electrode 606, AlGaN optical confining layer 608, GaN layer 610, quantum well layer 612, bonded patterned material layer 614, and top metal electrode 616. Also shown is the optical laser wave 618.

The period of the pattern in the layer 614 can also vary depending on the application considered. In the case of diffraction applications (electromagnetic wave diffraction approach), the period should be on the order of half of the wavelength of the light generated by the optoelectronic device. For GaN-based LEDs, this would correspond to periods of a few hundreds of nanometers.

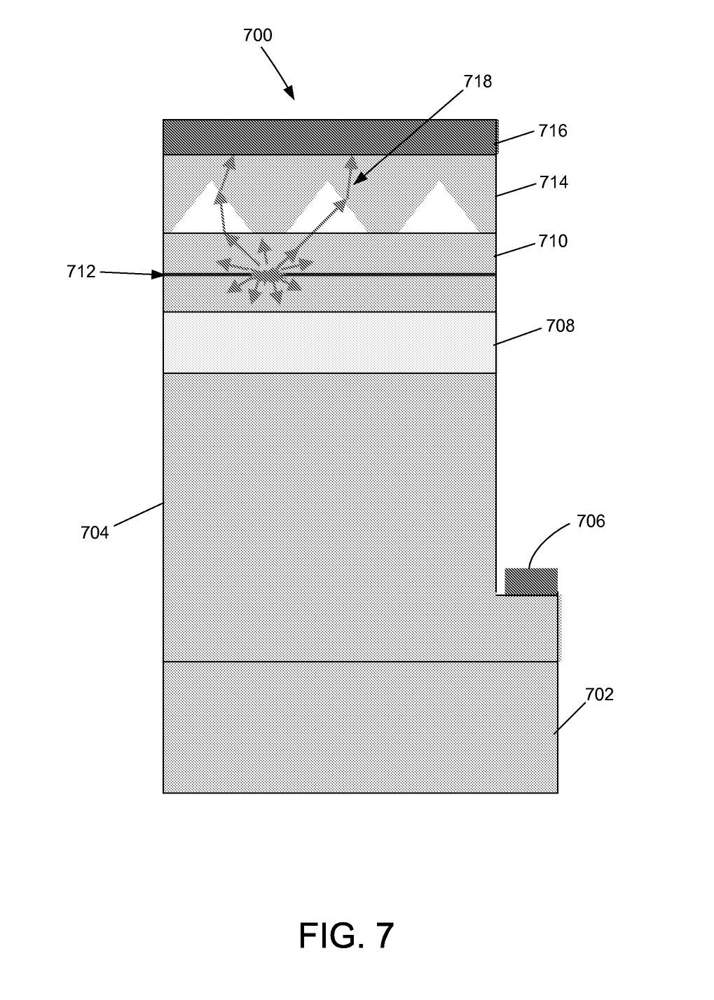

FIG. 7 is a schematic diagram of an LED structure incorporating embedded void-gap structures according to the present invention, wherein the void features are micron sized or larger so as to extract light through geometrical optics effects, i.e., by randomizing light rays propagating through the semiconductor original structure and the bonded material. The laser structure 700 includes a substrate 702, buffer layer 704, bottom metal electrode 706, AlGaN optical confining layer 708, GaN layer 710, quantum well layer 712, bonded patterned material layer 714, and top metal electrode 716. Also shown is the emitted light 718. The shapes of the embedded features within the bonded patterned material layer 714 were changed to illustrate other possible embodiments of the present invention. Specifically, the void gaps or holes in the patterned layer 714 can have any kind of shape. For example, polygonal, cylindrical or spherical holes are suitable for the application of the embedded structures either as diffracting or as scattering objects. In case of light scattering applications (geometrical optics approach), the period and size of the embedded void-gaps can be very large, on the order of a few microns or more (which is illustrated in FIG. 5, as well as FIG. 7).

Several configurations containing the embedded periodic structures through bonding of a patterned material can be created.

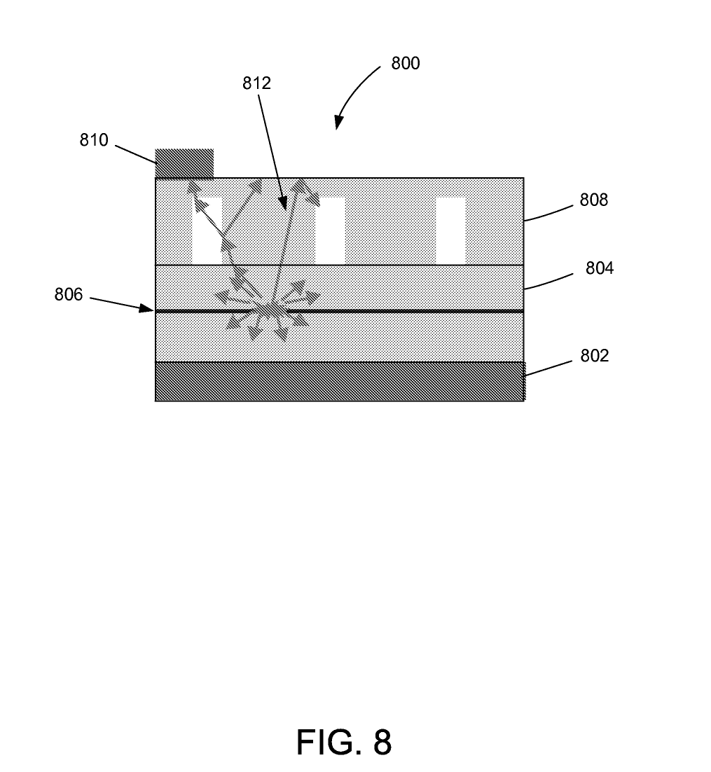

FIG. 8 is a schematic diagram of an LED structure incorporating embedded void-gap structures according to the present invention, wherein light is extracted through geometrical optics effects and the substrate has been removed. The laser structure 800 includes a bottom metal electrode 802, GaN layer 804, quantum well layer 806, bonded patterned material layer 808 comprised of a conductive transparent material, and top metal electrode 810. Also shown is the emitted light 812. This embodiment shows the patterned layer 808 bonded to the top surface of the active device structure following substrate removal to expose the bottom surface of the active device structure, thereby avoiding any light emission to the substrate.

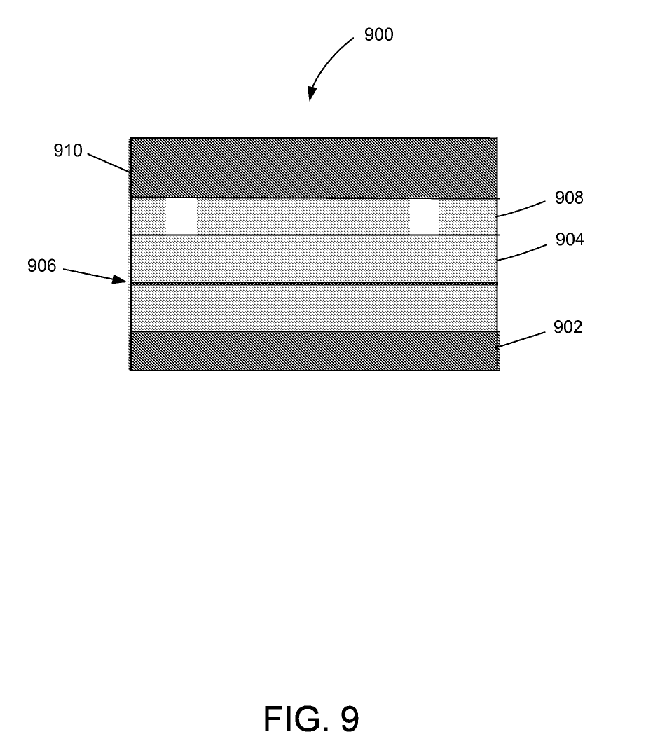

FIG. 9 is a schematic diagram of an LED structure incorporating embedded void-gap structures according to the present invention, wherein light is extracted through geometrical optics effects, wherein the substrate has been removed, and the void-gaps are obtained in two steps, by a double deposition or bonding of materials, a first layer being deposited or bonded having patterned air holes followed by a second layer being deposited or bonded on top of the first layer. The laser structure 900 includes a bottom metal electrode 902, GaN layer 904, quantum well layer 906, bonded patterned material layer 908 comprised of a conductive transparent material, and top metal electrode 910 that has been bonded to or deposited on the patterned layer 908. This embodiment shows that other layers can be bonded or grown on top of the patterned layer 908.

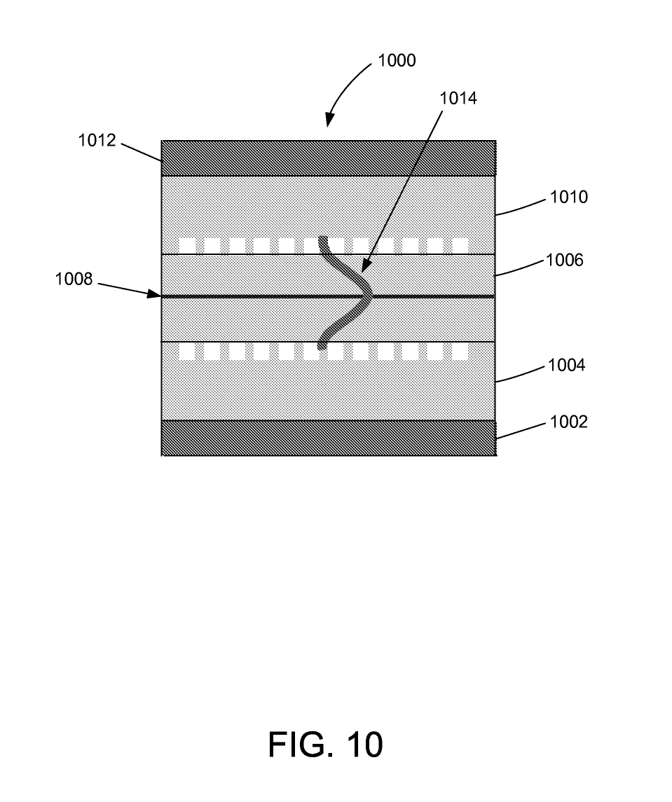

FIG. 10 is a schematic diagram of an LED structure incorporating embedded void-gap structures according to the present invention, wherein the substrate has been removed and subsequently the semiconductor was thinned to a sub-micron thickness, followed by the bonding of patterned material on both the top and bottom surfaces. The LED structure 1000 includes a bottom metal electrode 1002, bonded patterned material layer 1004, GaN layer 1006, quantum well layer 1008, bonded patterned material layer 1010, and top metal electrode 1012. Also shown is the optical laser wave 1014. This embodiment shows a thin active portion 1006, 1008 of the device, with embedded void-gap structures on the top and bottom surfaces thereof, by means for the patterned layers 1004, 1010, wherein the embedded void-gap structures are used to increase the diffraction of guided modes and/or to keep the guided light far from the interface where metal (lossy) contacts 1002, 1012 are deposited.

In addition, multiple patterned layers can be bonded on top of each other forming special configurations of embedded void-gap structures. For example, the bonding process can be repeated two or more times, on each side of the active device, after substrate removal and the thinning of the structure, resulting in a thin layer with embedded void-gap structures on both top and bottom surfaces.

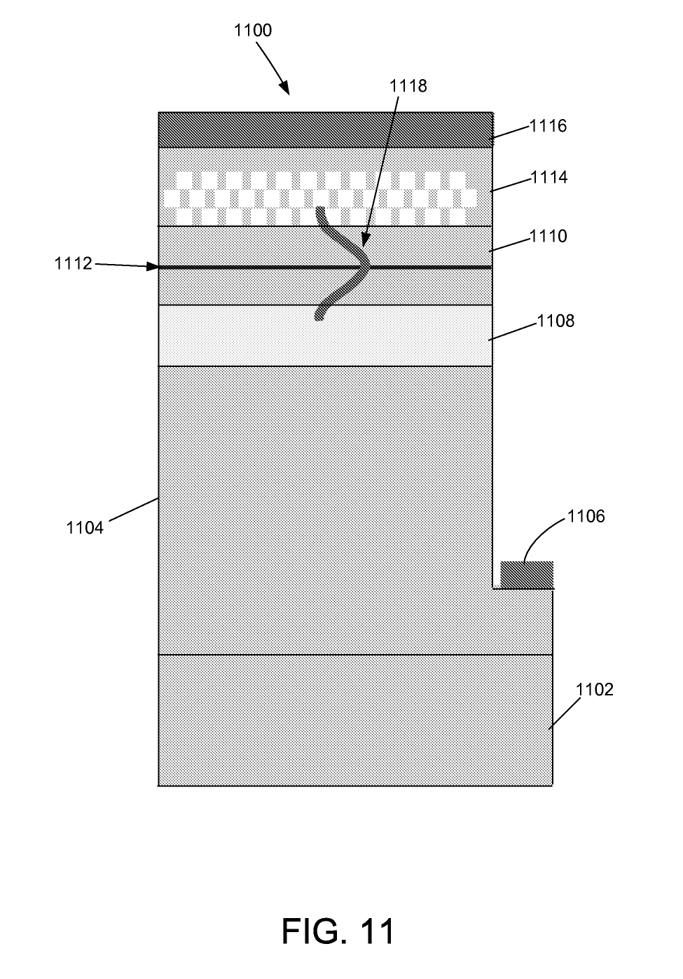

FIG. 11 is a schematic diagram of an LED structure incorporating embedded void-gap structures according to the present invention, wherein two or more patterned layers are piled up through bonding and precisely shifted to form a three-dimensional (3D) periodic structure (3D photonic crystals). The LED structure 1100 includes a substrate 1102, buffer layer 1104, bottom metal electrode 1106, AlGaN optical confining layer 1108, GaN layer 1110, quantum well layer 1112, bonded patterned material layer 1114, and top metal electrode 1116. Also shown is the emitted light 1118. In this embodiment, the patterned layer 1114 is comprised of several sub-layers of patterned material with void-gaps that are each positioned and shifted with respect to other sub-layers to form a three-dimensional (3D) photonic crystal structure.

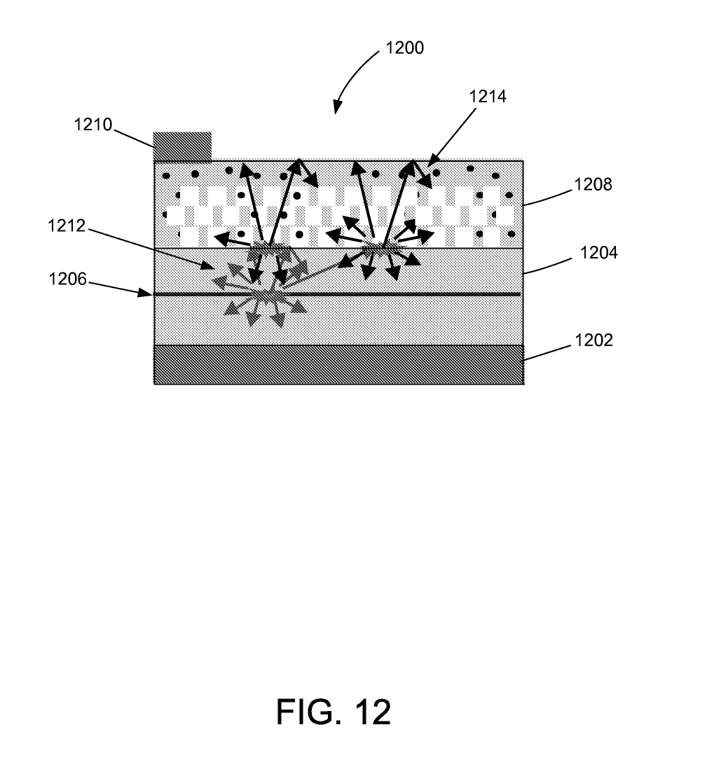

FIG. 12 is a schematic diagram of an LED structure incorporating embedded void-gap structures according to the present invention, wherein the bonded patterned layer contains frequency converter materials. The LED structure 1200 includes a bottom metal electrode 1202, GaN layer 1204, quantum well layer 1206, bonded patterned material layer 1208 comprised of both void-gaps (represented as squares) and light conversion elements (represented as dots), and top metal electrode 1210. Also shown is the emitted light 1212. The frequency of the light 1212 guided in the patterned layer 1208 is converted, thereby producing composed-color light, such as white light. The embedded void-gaps enhance the extraction of both the converted and original emitted light.

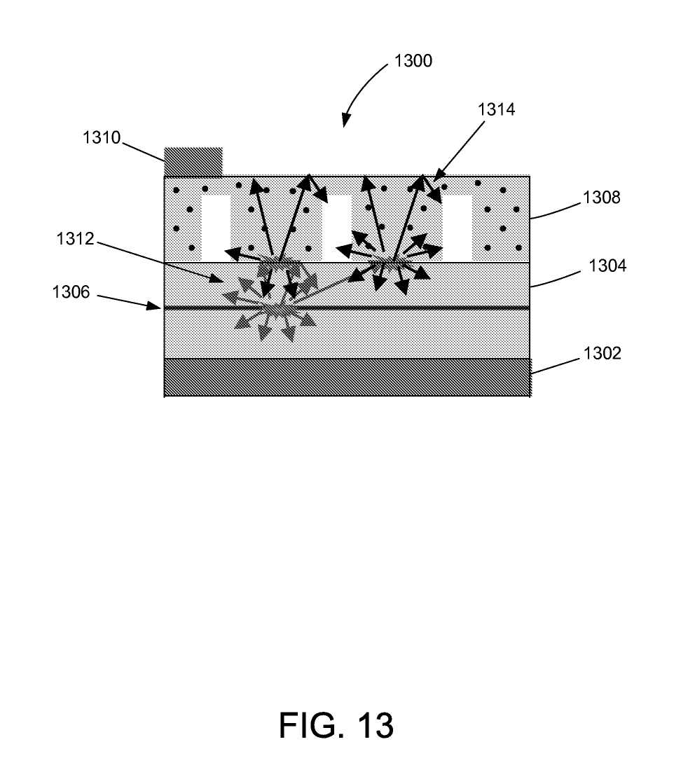

FIG. 13 is a schematic diagram of an LED structure incorporating concepts from FIGS. 11 and 12. The LED structure 1300 includes a bottom metal electrode 1302, GaN layer 1304, quantum well layer 1306, bonded patterned material layer 1308 comprised of both void-gaps (represented as rectangles) and light conversion elements (represented as dots), and top metal electrode 1310. Also shown is the emitted light 1312.

Some of the generated light by the optoelectronic device will also be guided in the patterned layer. The amount of guided light in the patterned layer can be controlled by changing the layer thickness or the depth of the objects in the pattern (i.e., the void-gaps or holes). The frequency of the guided light in the patterned layer can be changed, thereby resulting in white light emitting optoelectronic devices (or any other color composition). Light conversion active elements, such as dyes, quantum dots, phosphors, or GaInAlAsP-based material can be introduced in the patterned layer. These elements convert part of the light into other frequencies that combined to the original light emitted by the device can be used to produce secondary, ternary or any other color combination, including white. Guided light in the bonded layer interacts very well with the frequency converters (in the same layer) and the control over the amount of guided light (or the thickness of the patterned layer) provides control of the color mixing in the optoelectronic device (as illustrated in FIG. 11). Therefore, in this case, the application of the bonded patterned layer is twofold: it enhances light conversion through a better interaction of light and the conversion elements, and improves light extraction through diffraction or scattering.

Electrical and optical properties of the optoelectronic device can be both optimized by using a bonded patterned layer of conductive material. The patterned material can be a transparent conductor or semiconductor, such as ITO or ZnO. A thin conductive layer can be placed in between the active device structure and the bonded patterned layer for better current injection. A doped semiconductor layer could also be used as the bonded patterned layer, wherein an electrical contact is placed on the doped semiconductor layer.

A higher optical diffraction is obtained when the holes on the patterned layer are gaps or voids filled with air, due to the high refractive index contrast. Other materials can be used to fill the holes of the patterned layer to enhance some properties of this layer. For instance, the holes of the patterned layer can be partially or fully filled with dielectric, transparent conductive, metallic, semiconducting or frequency-converting materials.

The bonding of the patterned material can be made to a semiconductor whose active region (light emitting layer) is flat or patterned. A patterned active region means that the patterned holes are at least reaching the light-emitting layer. The patterned holes could extend partially or entirely through the active region.

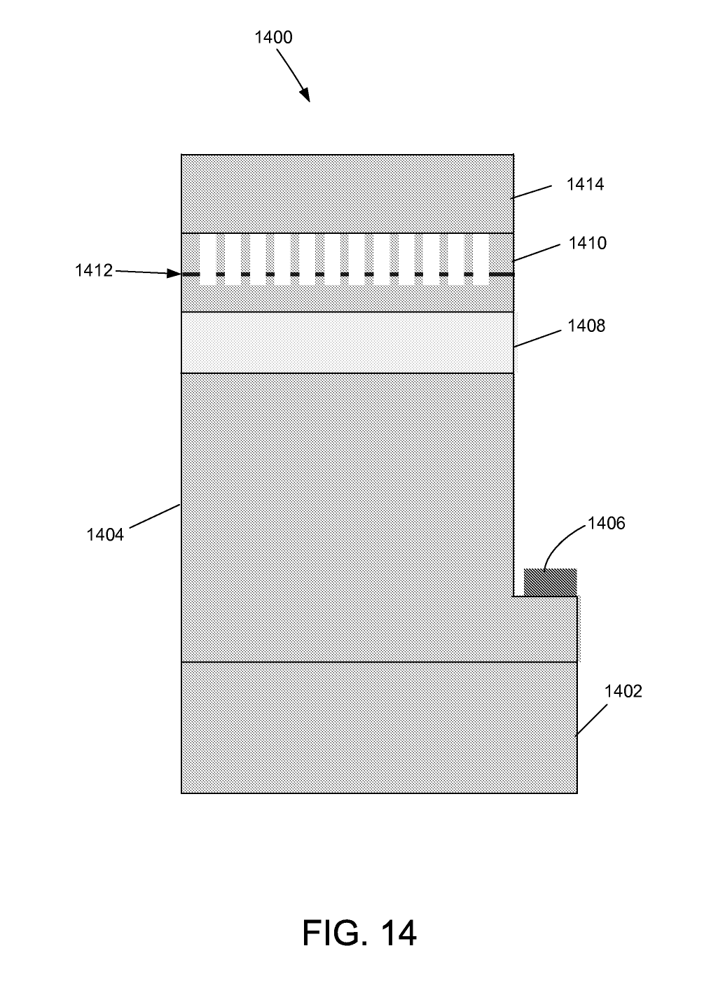

FIG. 14 is a schematic diagram of an LED structure according to the present invention, wherein the device was patterned to create a PhC and a flat layer was bonded over the PhC. The LED structure 1400 includes a substrate 1402, buffer layer 1404, bottom metal electrode 1406, AlGaN optical confining layer 1408, GaN layer 1410, quantum well layer 1412, and bonded flat material layer 1414. The flat layer 1414 could be any material, such as conductors, insulators, metals or semiconductors. For example, the bonded material could be a flat layer 1414 of SiC to be bonded over a patterned layer or substrate, such as GaN, ZnO or ITO, which was previously deposited over the other materials of the device. The electrical contact in the structure can be made on any side of the structure. One or more layers of conductive material of any kind can be placed over or below the bonded material, which can be on a top or bottom surface (or on any other surface) of the device.

Process Steps

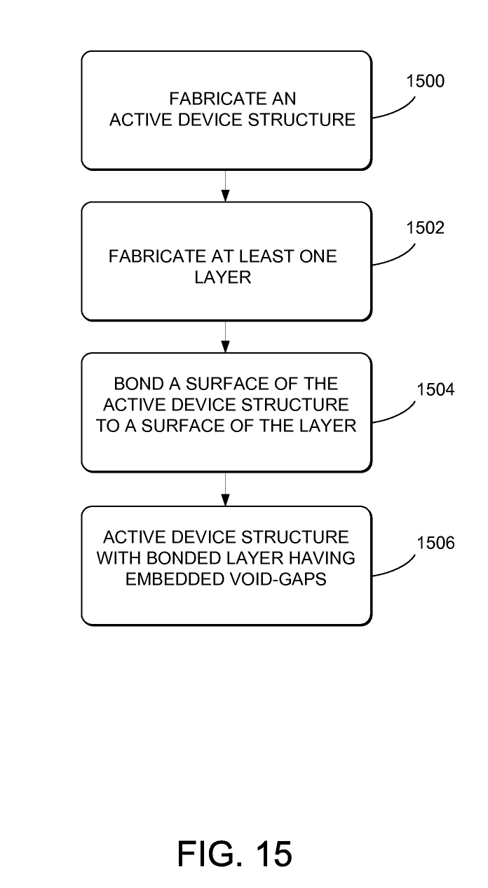

FIG. 15 is a flowchart that illustrates the process steps performed according to the preferred embodiment of the present invention. Specifically, the process steps comprise an improved method of fabrication of embedded patterned structures.

Block 1500 represents the step of fabricating an active device structure.

Block 1502 represents step of fabricating at least one layer.

Note that steps 1500 and 1502 can be performed in parallel.

Block 1504 represents the step of bonding the active device structure to the layer, wherein one or more embedded void-gaps are formed at an interface where a surface of the active device structure is bonded to a surface of the layer. In one embodiment, the surface of the layer is patterned and the surface of the active device structure is flat. In another embodiment, the surface of the active device structure is patterned and the surface of the layer is flat.

Note that a substrate may be removed from the active device structure to expose the surface of the active device structure. Moreover, one or more layers of the active device structure may be thinned after the substrate is removed and before the surface of the layer is bonded to the surface of the active device structure.

The void-gaps may be filled with air, a gas, a conductive material, or a dielectric material. In addition, the void-gaps may have a lower average index of refraction than the layer. Also, the layer may have a lower average index of refraction than the active device structure.

The void-gaps may comprise polygonal, cylindrical or spherical shaped features. In addition, the void-gaps may comprise: randomly shaped features, randomly distributed features, or periodically or quasi-periodically distributed shaped features. Also, the void-gaps may be arranged in a one dimensional pattern, two dimensional pattern, or three dimensional pattern. Moreover, the void-gaps may be: contiguously connected, formed of connecting holes, formed of connecting pillars, or formed of both connecting holes and connecting pillars.

Block 1504 may also represent additional fabrication steps. For example, one or more additional layers may be stacked or piled on the layer bonded to the active device structure. In addition, one or more electrically conductive layers are placed on a bottom or top surface of the active device structure. Moreover, one or more electrically conductive layers may be placed between the layer and the active device structure.

Block 1506 represents a device fabricated using steps 1500, 1502 and 1504. Specifically, this Block represents an optoelectronic device with embedded void-gap structures, comprising an active device structure bonded to at least one layer, wherein one or more embedded void-gaps are formed at an interface where a surface of the active device structure is bonded to a surface of the layer. For example, the optoelectronic device may be a light emitting diode (LED) or a laser.

### REFERENCES

The following references are incorporated by reference herein:
[1] T. A. Truong, L. M. Campos, E. Matioli, I. Meinel, C. J. Hawker, C. A. Weisbuch, and P. M. Petroff, “Light extraction from GaN-based light emitting diode structures with a noninvasive two-dimensional photonic crystal”, Applied Physics Letters 94, 023101, 2009.
[2] S. Uchida et al., IEEE Journal Of Selected Topics In Quantum Electronics, Vol. 9, No. 5, September/October 2003, p. 1252.
[3] U.S. Patent Publication No. 2006/0192217.
[4] U.S. Patent Publication No. 2008/0087909.
[5] U.S. Patent Publication No. 2006/0194359.
[6] U.S. Patent Publication No. 2007/0125995.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method of fabricating an optoelectronic device with embedded void-gap structures, comprising:
bonding an active device structure to at least one layer, wherein one or more embedded void-gaps are formed at an interface where a surface of the active device structure is bonded to a surface of the layer.

2. The method of claim 1, wherein the surface of the layer is patterned and the surface of the active device structure is flat, or wherein the surface of the active device structure is patterned and the surface of the layer is flat.

3. The method of claim 1, wherein the layer is comprised of an electrical conductor, transparent conductor, semiconductor, or metal.

4. The method of claim 1, further comprising a plurality of additional layers stacked or piled on the layer bonded to the active device structure.

5. The method of claim 1, wherein a substrate is removed from the active device structure to expose the surface of the active device structure.

6. The method of claim 5, wherein one or more layers of the active device structure are thinned after the substrate is removed and before the surface of the layer is bonded to the surface of the active device structure.

7. The method of claim 1, wherein the void-gaps are filled with air, a gas, a conductive material, or a dielectric material.

8. The method of claim 1, wherein the void-gaps have a lower average index of refraction than the layer.

9. The method of claim 1, wherein the layer has a lower average index of refraction than the active device structure.

10. The method of claim 1, wherein the void-gaps comprise polygonal, cylindrical or spherical shaped features.

11. The method of claim 1, wherein the void-gaps comprise:
randomly shaped features,
randomly distributed features, or
periodically or quasi-periodically distributed shaped features.

12. The method of claim 1, wherein the void-gaps are arranged in a one-dimensional pattern, two-dimensional pattern, or three-dimensional pattern.

13. The method of claim 1, wherein the void-gaps are:
contiguously connected,
formed of connecting holes,
formed of connecting pillars, or
formed of both connecting holes and connecting pillars.

14. The method of claim 1, wherein one or more electrically conductive layers are placed on a bottom or top surface of the active device structure.

15. The method of claim 1, wherein one or more electrically conductive layers are placed between the layer and the active device structure.

16. The method of claim 1, wherein the optoelectronic device is a light emitting diode (LED) or a laser.

17. A device fabricated using the method of claim 1.

18. An optoelectronic device with embedded void-gap structures, comprising:
an active device structure bonded to at least one layer, wherein one or more embedded void-gaps are formed at an interface where a surface of the active device structure is bonded to a surface of the layer.

19. The device of claim 18, wherein the surface of the layer is patterned and the surface of the active device structure is flat, or wherein the surface of the active device structure is patterned and the surface of the layer is flat.

20. The device of claim 18, wherein the layer is comprised of an electrical conductor, transparent conductor, semiconductor, or metal.

21. The device of claim 18, further comprising a plurality of additional layers stacked or piled on the layer bonded to the active device structure.

22. The device of claim 18, wherein a substrate is removed from the active device structure to expose the surface of the active device structure.

23. The device of claim 22, wherein one or more layers of the active device structure are thinned after the substrate is removed and before the surface of the layer is bonded to the surface of the active device structure.

24. The device of claim 18, wherein the void-gaps are filled with air, a gas, a conductive material, or a dielectric material.

25. The device of claim 18, wherein the void-gaps have a lower average index of refraction than the layer.

26. The device of claim 18, wherein the layer has a lower average index of refraction than the active device structure.

27. The device of claim 18, wherein the void-gaps comprise polygonal, cylindrical or spherical shaped features.

28. The device of claim 18, wherein the void-gaps comprise:
randomly shaped features,
randomly distributed features, or
periodically or quasi-periodically distributed shaped features.

29. The device of claim 18, wherein the void-gaps are arranged in a one-dimensional pattern, two-dimensional pattern, or three-dimensional pattern.

30. The device of claim 18, wherein the void-gaps are:
contiguously connected,
formed of connecting holes,
formed of connecting pillars, or
formed of both connecting holes and connecting pillars.

31. The device of claim 18, wherein one or more electrically conductive layers are placed on a bottom or top surface of the active device structure.

32. The device of claim 18, wherein one or more electrically conductive layers are placed between the layer and the active device structure.

33. The device of claim 18, wherein the optoelectronic device is a light emitting diode (LED) or a laser.
